(19) United States
(12) Patent Application Publication
(10) Pub. No.: US 2012/0319545 A1
(43) Pub. Date: Dec. 20, 2012

(54) ENCLOSURE OF ELECTRONIC DEVICE

(75) Inventors: YAO-TING CHANG, Tu-Cheng (TW); HUNG-CHOU CHAN, Tu-Cheng (TW)

(73) Assignee: HON HAI PRECISION INDUSTRY CO., LTD., Tu-Cheng (TW)

(21) Appl. No.: 13/214,235

(22) Filed: Aug. 22, 2011

(30) Foreign Application Priority Data
Jun. 16, 2011 (TW) 100120994

(51) Int. Cl. H05K 5/02

(52) U.S. Cl. 312/223.1

(57) ABSTRACT

An enclosure includes a main body with a sidewall. The sidewall defines a first opening. A three dimensional shaped mesh cover is attached to the sidewall to cover the first opening. The mesh cover defines a second opening aligning with the first opening.

### BACKGROUND

1. Technical Field

The present disclosure relates to enclosures and, more particularly, to an enclosure of an electronic device.

2. Description of Related Art

An electronic device, such as a server or a computer, usually defines a plurality of vents for heat dissipation. A flat mesh cover is usually used to cover the vents for filtering dust. However, the cover interferes with airflow, thus reducing the effectiveness of heat dissipation.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a first embodiment of an enclosure.

FIG. 2 is an assembled, isometric view of FIG. 1.

FIG. 3 is an exploded, isometric view of a second embodiment of an enclosure.

FIG. 4 is an assembled, isometric view of FIG. 3.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

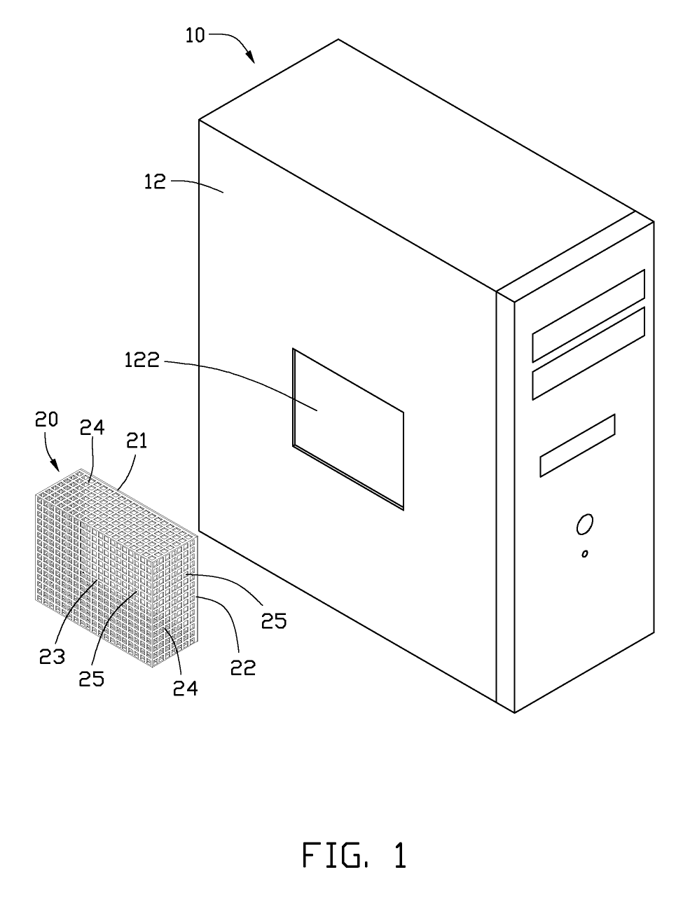

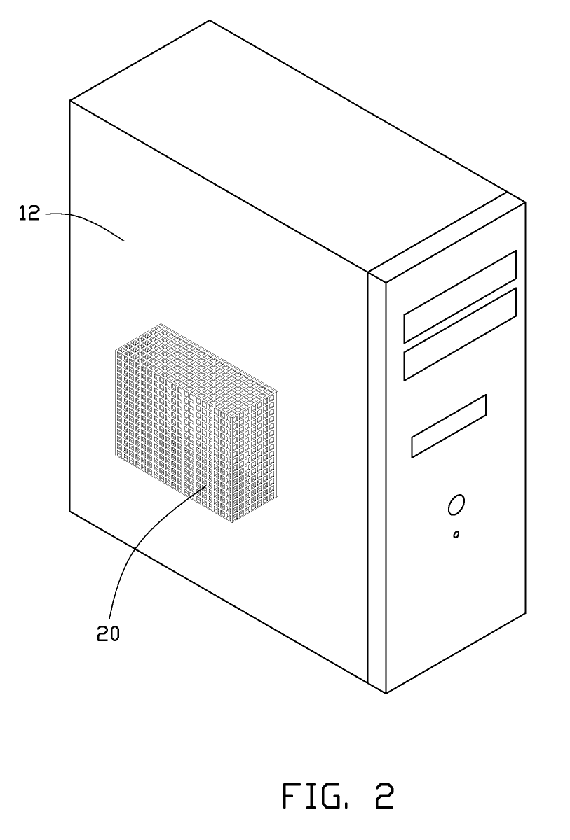

Referring to FIG. 1 and FIG. 2, a first exemplary embodiment of an enclosure of an electronic device includes a main body 10 for enclosing a motherboard and a plurality of electronic components to execute the function of the electronic device, and a mesh cover 20 attached to the main body 10.

The main body 10 includes a sidewall 12 defining an opening 122. In the first embodiment, the opening 122 is rectangular.

The mesh cover 20 is a rectangular box, and includes a rectangular main plate 23, and four side plates 24 perpendicularly extending from sides of the main plate 23. A side of the mesh cover 20 defines an opening 21 bounded by sides of the side plates 24 opposite to the main plate 23. An attaching member 22 is fixed to the sides of the side plates 24 around the opening 21. The attaching member 22 mounts the mesh cover 20 to the sidewall 12 to cover the opening 122, with the opening 21 aligning with the opening 122. The main plate 23 and the side plates 24 define a plurality of vents 25 communicating with the opening 21. In the embodiment, the attaching member 22 is made of magnetic material, which can be attracted to the sidewall 12. In another embodiment, the attaching member 22 also may be adhesive.

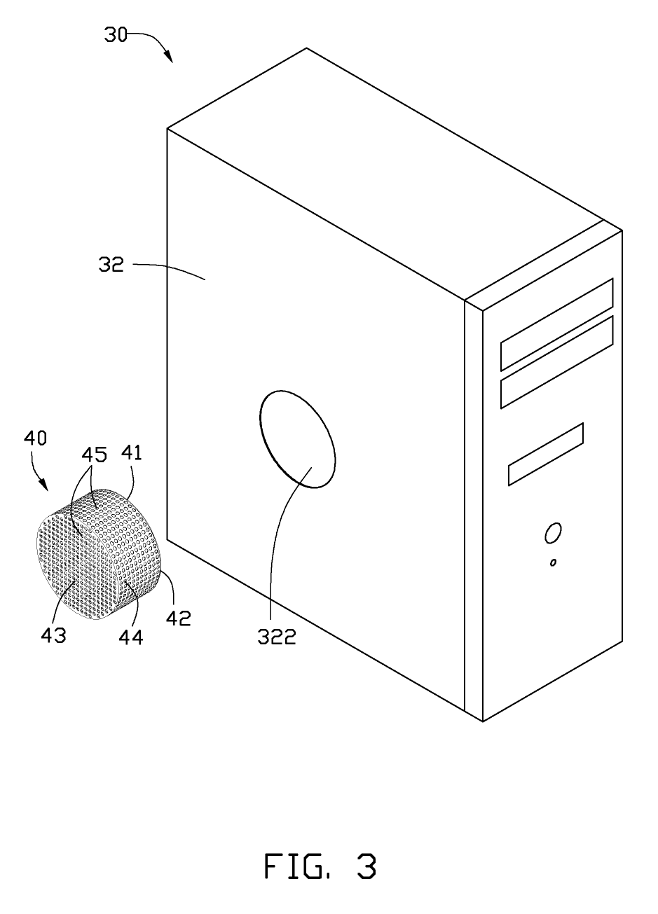

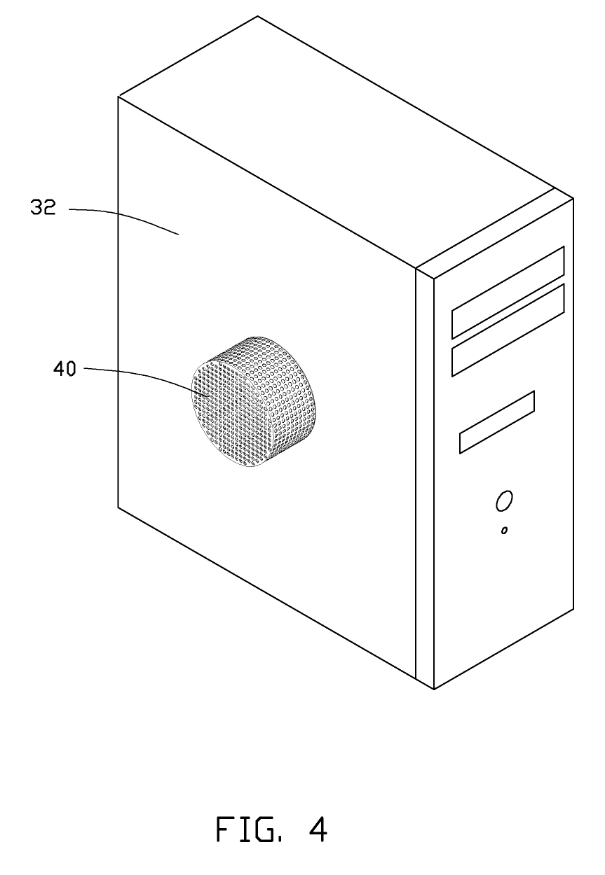

Referring to FIG. 3 and FIG. 4, a second exemplary embodiment of an enclosure includes a main body 30 and a mesh cover 40 attached to the main body 30.

The main body 30 includes a sidewall 32 defining a round opening 322.

The mesh cover 40 is a columnar box, and includes a round main plate 43, and a circular side plate 44 perpendicularly extending from a circumference of the main plate 43. A side of the side plate 44 opposite to the main plate 43 bounds an opening 41. An attaching member 42 is fixed to the side of the side plate 44 around the opening 41. The main plate 43 and the side plate 44 define a plurality of vents 45. The attaching member 42 mounts the mesh cover 40 to the sidewall 32 to cover the opening 322, with the opening 41 aligning with the opening 322. In the embodiment, the attaching member 42 is made of magnetic material, which can be attracted to the sidewall 32. In another embodiment, the attaching member 42 also may be adhesive.

Obviously, the shapes of the mesh cover 20 and 40 can be changed according to the shape of the opening 122 and 322. The mesh covers 20 and 40 may be made of metal for providing electro-magnetic radiation shielding. The mesh covers 20 and 40 are not flat and so provide an increased surface area for venting, which can improve heat dissipation.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An enclosure comprising:
a main body comprising a sidewall, the sidewall defining a first opening; and
a three dimensional shaped mesh cover attached to the sidewall to cover the first opening, the mesh cover defining a second opening aligning with the first opening.

2. The enclosure of claim 1, wherein the first opening is rectangular, the mesh cover is a rectangular box, and comprises a rectangular main plate, and four side plates extending from sides of the main plate, the second opening is bounded by sides of the side plates opposite to the main plate.

3. The enclosure of claim 1, wherein the first opening is round, the mesh cover is a columnar box, and comprises a round main plate, and a circular side plate extending from the circumference of the main plate, the second opening is bounded by a side of the side plate opposite to the main plate.

4. The enclosure of claim 1, further comprising an attaching member mounted to the mesh cover around the second opening, to mount the mesh cover to the sidewall.

5. The enclosure of claim 4, wherein the attaching member is made of magnetic material to be attracted to the sidewall.

6. The enclosure of claim 4, wherein the attaching member is adhesive to be adhered to the sidewall.
